(19) United States
(12) Patent Application Publication
(10) Pub. No.: US 2021/0152129 A1
(43) Pub. Date: May 20, 2021

(54) SUPPLY CIRCUIT

(71) Applicant: ASELSAN ELEKTRONIK SANAYI VE TICARET ANONIM SIRKETI, Ankara (TR)

(72) Inventors: Ahmet AKTUG, Ankara (TR); Yigit AYDOGAN, Ankara (TR)

(73) Assignee: ASELSAN ELEKTRONIK SANAYI VE TICARET ANONIM SIRKETI, Ankara (TR)

(21) Appl. No.: 16/605,254

(22) PCT Filed: Jul. 2, 2018
(86) PCT No.: PCT/TR2018/050336

§ 371 Date: Oct. 15, 2019

(30) Foreign Application Priority Data
Jul. 17, 2017 (TR) 2017/10491

(51) Int. Cl. H03F 1/02; H03F 3/24; H03F 3/193; H03F 1/30

(52) U.S. Cl. CPC H03F 1/0211; H03F 3/245; H03F 2200/18; H03F 1/301; H03F 3/193

(57) ABSTRACT

A supply circuit providing transmission of a control signal to gate leg by a power transistor. The supply circuit includes a primary transistor, a primary resistance connected between the primary transistor drain leg and ground; a secondary resistant connected to supply leg of primary transistor on one side and to gate leg, the primary transistor and a power supply from other side; a secondary transistor connected to drain leg of primary transistor from gate leg, connected to ground from drain leg and connected to the power supply by means of a third resistance from supply leg and a control signal output connected to the secondary transistor supply leg, providing transmission of a control signal by power transistor to a gate leg.

### CROSS REFERENCE TO THE RELATED APPLICATIONS

This application is the national phase entry of the International Application No. PCT/TR2018/050336, filed on Jul. 2, 2018, which is based upon and claimed priority to Turkish Patent Application No. 2017/10491, filed on Jul. 17, 2017 the entire contents of which are incorporated herein by reference.

### TECHNICAL FIELD

Present invention relates to on-chip current drivable gate supply circuits appropriate particularly for use at RF/MW power amplifiers.

### BACKGROUND

Multi-layer high power RF/MW power amplifiers (power transistor) are used to amplify power of radio frequency (RF) and microwave (MW) signals. In said multi-layer high power RF/MW power amplifier, RF-MW signal to be amplified and a control signal are connected to a gate of a transistor and RF/MW signal is received from drain leg of said transistor. Here said control signal (gate signal) controls operation of transistor. However, RF-MW signals of high power may create opposite direction current at gate leg of the transistor. Since this current changes the gate voltage of the transistor, operation of transistor can not be controlled by said control signal at the desired sensitivity.

In order to control operation of said power amplifier in a sensitive manner, the strength of the gate supply circuit providing control currency to transistor against various environmental conditions should be high. The environmental conditions mentioned here are temperature change, threshold voltage change, resistance value change, supply voltage change and change in value of current from gate. The embodiments in the related art use supply circuits providing strength against various environmental conditions. A supply circuit in a sample embodiment comprised of a power supply, a resistance connected to the power supply and a diode connected between resistance and ground line. The control signal in that application is received between diode and resistance, and supplied to gate leg. Here the positive current produced by RF/MW signal at gate leg is grounded on diode and therefore gate voltage at positive currents is mostly constant. However, in case RF/MW signal creates negative current at gate leg in said system, changes occur in gate voltage since the current flows through resistance. Said supply circuit does not have resistance against factors such as resistance value change, supply voltage change either.

### SUMMARY

Present invention relates to a supply circuit providing transmission of a control signal to gate leg by at least a power transistor. Said supply circuit comprises of at least a primary transistor, at least a primary resistance connected between said primary transistor drain leg and ground; at least a secondary resistance connected to supply leg of primary transistor supply leg on one side and to gate leg and a power source of the primary transistor from other side; at least secondary transistor connected to drain leg of primary transistor from gate leg, connected to ground from drain leg and connected to said power supply by means of at least a third resistance from supply leg and at least a control signal output connected to said secondary transistor supply leg, providing transmission of a control signal by power transistor to a gate leg.

The supply circuit disclosed under the present invention provides that the supply leg voltage of the secondary transistor is influenced by environmental factors thanks to connection of gate leg of secondary transistor to drain leg of the primary transistor. Thus thanks to receiving a control signal from control signal output connected to supply leg of the secondary transistor to drive power transistor, driving of said power transistor is provided in a controlled manner.

Purpose of the invention is to develop an active gate supply circuit appropriate for use in RF-MW power amplifiers.

Another purpose of the invention is to develop a supply circuit of high strength against environmental conditions.

Another purpose of the invention is to develop a supply circuit whose change of control signal even generated under changing environmental conditions is low.

### BRIEF DESCRIPTION OF THE DRAWINGS

The figures of illustrative embodiments of the supply circuit disclosed under the invention are given in the following figures:

FIG. 1 shows a circuit diagram of supply circuit.

FIG. 2 shows a circuit diagram of an alternative embodiment of the supply circuit.

FIG. 3 shows a graphic of change of control signal voltage of supply circuit of the invention according to input signal current value.

The parts indicated in the figures have been designated separate numbers and said numbers are given below:
Signal input (I)
Signal output (O)
Power transistor (P)
Gate leg (G)
Supply leg (S)
Drain leg (D)
Primary transistor (T1)
Secondary transistor (T2)
Control signal output (C)
Power supply (A)
Primary resistance (R1, R1a, R1b, R1c)
Secondary resistance (R2)
Third resistance (R3)

### DETAILED DESCRIPTION OF THE EMBODIMENTS

Power amplifiers used to amplify power of Radio frequency—(RF) and microwave (MW) signals are generally controlled by a control signal received from a gate leg. However, problems such as distortion of said control signal can be encountered because of opposite direction current production at transistor gate leg, particularly at high power levels. For that reason, the invention develops an active gate supply circuit of high strength against various environmental conditions and appropriate for use at RF/MW power amplifiers.

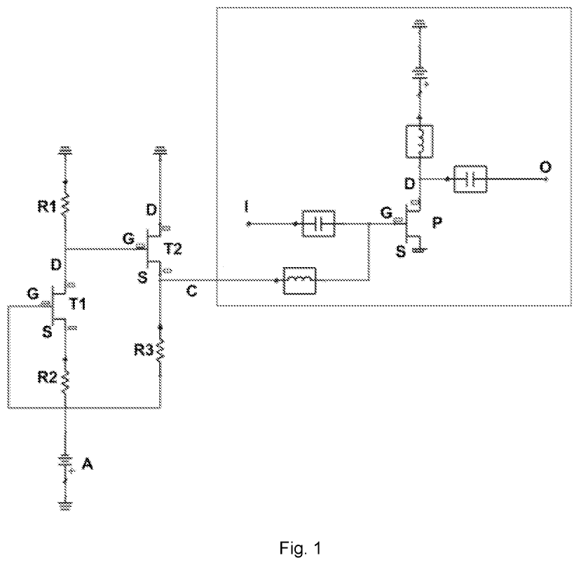

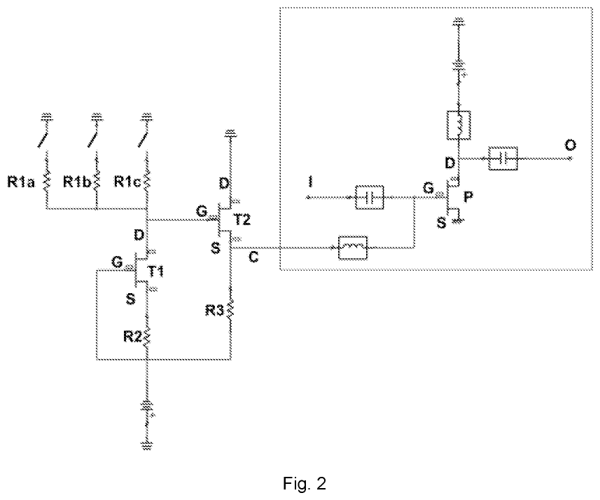

The supply circuit developed under the invention and of which illustrative views are given in FIGS. 1 and 2 provides transmission of a control signal to a gate leg (G) by at least a power transistor (P) (for instance a MOSFET transistor). Said supply circuit comprises of at least a primary transistor (T1) (for instance a MOSFET transistor); at least a primary resistance (R1) connected between said primary transistor (T1) drain leg (D) and ground; at least a secondary resistance (R2) connected to supply leg (S) of primary transistor (T1) on one side and to gate leg (G) the primary transistor (T1) and a power supply (A) from other side; at least secondary transistor (T2) (for instance a MOSFET transistor) connected to drain leg (D) of primary transistor (T1) from gate leg (G), connected to ground from drain leg (D) and connected to said power supply (A) by means of at least a third resistance (R3) from supply leg (S) (also to gate leg (G) of the primary transistor (T1)) and at least a control signal output (C) connected to said secondary transistor (T2) supply leg (S), providing transmission of a control signal by power transistor to a gate leg (G)

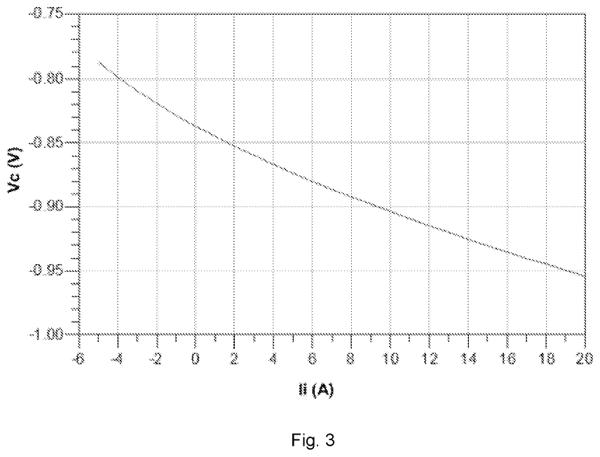

In an illustrative application of the invention, said power transistor (P) receives an input signal from a signal input (I) connected to gate leg (G) and a control signal from control signal output (C) connected to gate leg (G). Power of said input signal is amplified in line with received control signal and a signal amplified from a signal output (0) is received. Said power supply (A) mentioned in this application provides voltage in negative direction. Said voltage in negative direction is directly applied to primary transistor (T1) gate leg (G), to supply leg (S) of primary transistor (T1) via the secondary resistance (R2) and to supply leg (S) of the secondary transistor (T2) via the third resistance (R3). In this case the secondary transistor (T2) works in linear zone. Here since said control signal is received from control signal output (C) connected to supply leg (S) of the secondary transistor (T2), even it takes current from gate leg (G) subject to input signal (I) of power transistor (P), the effect of such current to change the voltage value of control signal (to supply leg (S) of the secondary transistor (T2)) is considerably low because the taken current is not via any resistance. In an illustrative application, graphic showing change of voltage of control signal (Vc) according to input signal current (Ii) is shown in FIG. 3. As shown in said graphic, even when value of input signal current (Ii) is relatively high (20 A) and relatively low (−6 A), voltage of control signal (Vc) is influenced by said current value slightly. Thus strength of input signal taken from signal input (I) of the supply circuit developed under the invention is provided to be high according to current change. However, since gate leg (G) of the secondary transistor (T2) is connected to drain leg (D) of the primary transistor (T1), even if the voltage value of the power supply (A) changes, voltage of gate leg (G) of the secondary transistor (T2) almost does not change. Here, since the secondary transistor (T2) works in linear zone, even when voltage value of the power supply (A) changes, change in voltage (Vgs) of the secondary transistor (T2) from gate leg (G) to supply leg (S) remains limited. Thus when voltage value of the power supply (A) changes, change in voltage value of the secondary transistor (T2) supply leg (S) (this value is the voltage of control signal) is little. In other words, it is provided that the strength of voltage of control signal is high against change in voltage of power supply (A). In an illustrative application, when voltage value of power supply (A) is selected as −5 V, change of said voltage by 1 V (20%) causes a change about 0.07 V (7.7%) in −0.91 V control voltage signal. Also threshold voltage changes are taken into account in the supply circuit developed under the invention. Threshold voltage changes in similar way in all of produced transistors (T1, T2, P) when chip designs are considered. For that reason, contrary to other parameters, since when threshold voltage changes, threshold voltages of the primary transistor (T1), the secondary transistor (T2) and power transistor (P) changes in similar direction, control signal should not remain constant but change in the same rate. In the present invention, gate leg (G) voltage of the secondary transistor (T2) shows two folds of threshold voltage change by means of the primary resistance (R1) and the secondary resistance (R2) values, since threshold voltage of the secondary transistor (T2) also changes, voltage of supply leg (S) of the secondary transistor (T2) changes in parallel to change in threshold voltage. Thus changes in currents taken from drain leg (D) of the power transistor (P) decreases considerably despite changes in threshold voltage. In addition to these, since voltage value of the gate (G) of the secondary transistor (T2) is partially subject to the primary resistance (R1) and the secondary resistance (R2) (not directly subject to) and current flowing through the secondary transistor (T2) is partially subject to the third resistance (R3), change in one of said resistances (R1, R2, R3) due to any environmental factors, for instance, affects the voltage value of supply leg (S) of the secondary transistor (T2) in relatively low level. Thus supply circuit developed under the present invention has high resistance against various environmental factors.

In a preferred embodiment of the invention, said primary resistance (R1) is of a fixed resistance structure. In an alternative embodiment, the primary resistance (R1) is of an adjustable resistance (like potentiometer). Thus changes that might occur in voltage value of control signal due to environmental factors can be compensated by means of changing resistant value of the primary resistance (R1).

In another embodiment of the invention, the supply circuit developed under the invention is of a chip structure. In this embodiment, since it is not possible to access to components of supply circuit, intervention to control signal obtained by supply circuit is not possible. However, it may be required to use different control signal in different power transistors (P). For that reason, in a preferred embodiment of the invention, as shown in FIG. 2, the supply circuit comprises of at least two primary resistances (R1a, R1b, R1c) wherein each has different resistant value. A common terminal of said primary resistances (R1a, R1b, R1c) referred to in said embodiment is connected to drain leg (D) of the primary transistor (T1) and the terminals which are not common are connected to ground in a controlled manner. Connection of said not controlled terminals to the ground is provided by means of output of each not common terminals in the supply circuit of chip structure as an output leg. Thus thanks to checking the leg connected to ground, it is possible to select which the primary resistance (R1a, R1b, R1c) will be active. Here it is made possible to obtain a desired resistance value by means of primary resistances (R1a, R1b, R1c) of parallel structure upon selection of more than one primary resistance (R1a, R1b, R1c) as active resistance (for instance, seven different resistant values can be obtained by use of three different primary resistances (R1a, R1b, R1c)). Thus it is enabled to use a single supply circuit of chip structure together with different power transistors (P).

The supply circuit disclosed under the present invention provides that the supply leg (S) voltage of the secondary transistor (T2) is influenced by environmental factors thanks to connection of gate leg (G) of secondary transistor (T2) to drain leg (D) of the primary transistor (T1). Thus thanks to receiving a control signal from control signal output (C) connected to supply leg (S) of the secondary transistor (T2) to drive power transistor (P), driving of said power transistor (P) is provided in a controlled manner.

1. A supply circuit providing transmission of a control signal to a gate leg of (G) a power transistor, comprising:
a primary transistor;
a primary resistance connected between a drain leg of the primary transistor and a ground;
a secondary resistance connected to a supply leg of the primary transistor on one side and to gate leg of the primary transistor and a power supply from an other side;
a secondary transistor, wherein, a gate leg of the secondary transistor is connected to the drain leg ED) of the primary transistor, a drain leg of the secondary transistor is connected to the ground and a supply leg of the secondary transistor is connected to the power supply through a third resistance; and
a control signal output connected to the supply leg of the secondary transistor, providing the transmission of the control signal to the gate leg of the power.

2. The supply circuit according to claim 1, wherein, the primary resistance is of a fixed resistance structure.

3. The supply circuit according to claim 1, wherein, the primary resistance is of an adjustable resistance structure.

4. The supply circuit according to claim 1, wherein, the supply circuit is of a chip structure.

5. The supply circuit according to claim 1, wherein, the supply circuit comprises of at least two primary resistances each having a different resistance value.

6. The supply circuit according to claim 4, wherein, the supply circuit comprises at least two primary resistances each having a different resistance value.
